(19) United States
(12) Patent Application Publication
(10) Pub. No.: US 2026/0316265 A1
(43) Pub. Date: Oct. 15, 2026

(54) Material Handling System

(71) Applicant: Persimmon Technologies Corporation, Wakefield, MA (US)

(72) Inventor: Martin Hosek, Salem, NH (US)

(21) Appl. No.: 19/643,036

(22) Filed: Apr. 9, 2026

Related U.S. Application Data
(60) Provisional application No. 63/785,697, filed on Apr. 9, 2025.

(51) Int. Cl. B25J 9/12; B25J 9/16; B25J 13/08

(52) U.S. Cl. CPC B25J 9/12; B25J 9/161; B25J 13/088

(57) ABSTRACT

An apparatus includes a platform comprising a plurality of windings; a platen having a first surface facing the plurality of windings and a second surface opposing the first surface, the first surface comprising a plurality of magnets; and an end effector coupled to the second surface of the platen. The windings are configured to be energized to interact with the plurality of magnets to exert independently controllable horizontal and vertical forces in at least three different non-collinear locations on the platen.

### CROSS REFERENCE TO RELATED APPLICATION

This application claims priority under 35 USC 119(e) to U.S. Provisional Application No. 63/785,697, filed Apr. 9, 2025, which is hereby incorporated by reference in its entirety.

### BACKGROUND

### Technical Field

The exemplary and non-limiting embodiments disclosed herein relate generally to material handling systems and, more particularly, to material handling systems for clean-and vacuum-environment applications.

### Brief Description of Prior Developments

Some material handling systems employ robots in the manufacture of various products that include semiconductor materials. These robots generally incorporate motors, drive shafts, and belt/pulley arrangements that are configured to cause the rotation of one or more arms, each of the arms comprising one or more linkages such as an upper arm and a forearm. One or more end effectors may be attached to non-driven ends of the arms, where the end effectors support one or more workpieces thereon, such as semiconductor wafers or glass panels. The robots are used to move the workpieces between processing chambers, load locks, and/or storage cassettes. The mechanical arrangements of such robots may be prone to causing contamination and outgassing effects, which may affect the quality of a finished semiconductor product.

### SUMMARY

The following summary is merely intended to be exemplary and is not intended to limit the scope of the claims.

In one aspect, an apparatus comprises a platform comprising a plurality of windings; a platen having a first surface facing the plurality of windings and a second surface opposing the first surface, the first surface comprising a plurality of magnets; and an end effector coupled to the second surface of the platen. The windings are configured to be energized to interact with the plurality of magnets to exert independently controllable horizontal and vertical forces in at least three different non-collinear locations on the platen.

In another aspect, a material handling system comprises a chamber having at least one processing station extending therefrom; a material handling apparatus associated with the chamber, the material handling apparatus comprising a platform comprising a plurality of windings, a platen having a first surface facing the plurality of windings and a second surface opposing the first surface, the first surface comprising a plurality of permanent magnets of alternating polarity arranged in an array, and an end effector coupled to the second surface of the platen. The windings are configured to be energized to interact with the plurality of magnets to exert independently controllable horizontal and vertical forces in at least three different non-collinear locations on the platen. Operation of the material handling apparatus in the chamber comprises exerting the independently controllable horizontal and vertical forces on the platen to controllably move the end effector into or out of the at least one processing station.

In another aspect, a material handling system comprises a chamber having at least one processing station; a material handling apparatus associated with the chamber, the material handling apparatus comprising a platform comprising a plurality of windings, at least one of the windings comprising three phased inductors arranged to provide magnetic commutation, a platen having a first surface facing the plurality of windings and a second surface opposing the first surface, the first surface comprising a plurality of permanent magnets of alternating polarity arranged in an array, and an end effector coupled to the second surface of the platen; at least one processor; and at least one memory storing instructions that, when executed with the at least one processor, cause the material handling system to energize at least one of the windings of the plurality of windings, provide a magnetic field from the energized at least one winding relative to the array of magnets on the platen, using the magnetic field, exert a force on the platen to move the platen relative to the platform, and move the end effector into or out of the at least one processing station.

### BRIEF DESCRIPTION OF THE DRAWINGS

The foregoing aspects and other features are explained in the following description, taken in connection with the accompanying drawings, wherein:

FIG. 1A is a schematic representation of a top view of one example embodiment of a material handling system;

FIG. 1B is a schematic representation of a sectional side view of the material handling system of FIG. 1A;

FIG. 1C is a schematic representation of a sectional side view of a magnet array of a platen and actuation windings on a support platform of the material handling system of FIGS. 1A and 1B;

FIG. 1D is a schematic representation of a sectional side view of a material handling system incorporating a movable positioning stage;

FIGS. 2A-2F are schematic representations of extensions of an end effector of the material handling system of FIGS. 1A-1C;

FIG. 3A is a schematic representation of a top view of another example embodiment of a material handling system;

FIG. 3B is a schematic representation of a sectional side view of the material handling system of FIG. 3A;

FIG. 4 is a schematic representation of a top view of another example embodiment of a material handling system;

FIG. 5 is a schematic representation of a top view of another example embodiment of a material handling system;

FIG. 6 is a schematic representation of a top view of another example embodiment of a material handling system;

FIG. 7A is a schematic representation of a top view of another example embodiment of a material handling system;

FIG. 7B is a schematic representation of a sectional side view of the material handling system of FIG. 7A;

FIG. 8 is a schematic representation of a top view of another example embodiment of a material handling system;

FIG. 9A, is a schematic representation of windings that are arranged horizontally and vertically;

FIG. 9B is a schematic representation of a platen on which magnets are arranged in diagonal rows and having alternating polarities;

FIG. 10A is a schematic representation of horizontal and vertical windings arranged one on top of the other;

FIG. 10B is a schematic representation of magnets arranged in diagonal rows and having alternating polarities;

FIG. 11A is a schematic representation of two sets of windings that are one on top of the other and angled;

FIG. 11B is a schematic representation of magnets arranged in rows and spaced horizontally and vertically;

FIG. 12 is a schematic representation of a material handling system having a counterbalance;

FIG. 13 is a schematic representation of a material handling system having pivoting arms; and

FIG. 14 is a schematic representation of a material handling system having articulating linkages.

### DETAILED DESCRIPTION OF EMBODIMENTS

The example embodiments described herein are directed to material handling systems (for example, systems employing robots) suitable for clean-and vacuum-environment applications, such as handling of silicon and glass substrates in processes for the manufacture of semiconductors, light emitting diodes (LED), liquid crystal displays (LCD), and the like. The systems and apparatuses described herein are more particularly directed to the elimination of undesirable contamination and outgassing effects associated with mechanical arrangements, such as bearings and rails, utilized in conventional material handling solutions.

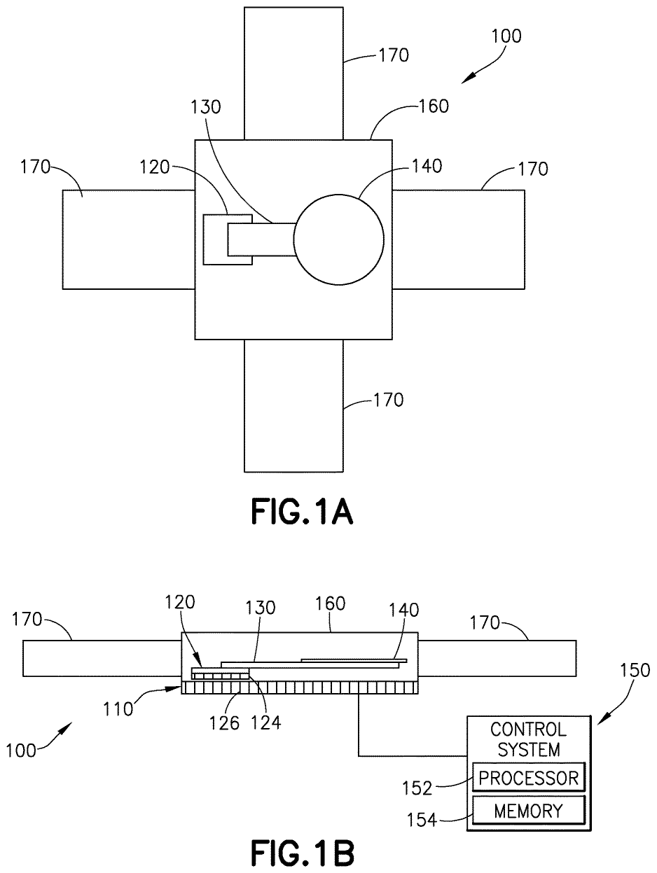

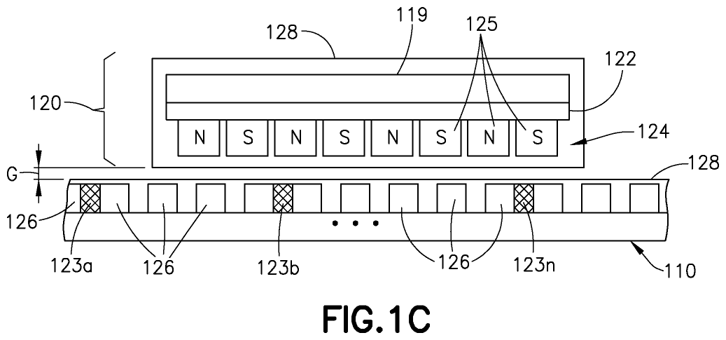

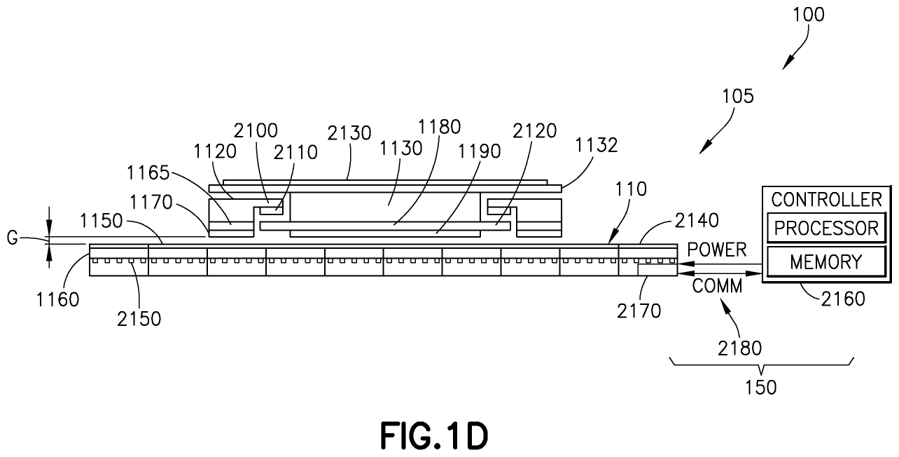

Referring to FIGS. 1A and 1B, one example embodiment of a material handling system is shown generally at 100 and is hereinafter referred to as “system 100.” System 100 comprises a support platform 110 having a substantially planar surface, at least one movable platen 120 positioned above the planar surface of the support platform 110 and separated therefrom by a gap (when system 100 is energized), and at least one end effector 130 coupled to the platen 120 and configured to carry a workpiece 140, such as one or more silicon or glass substrates. The support platform 110, the platen 120, and the end effector 130 may be located in a chamber 160.

As indicated in FIG. 1C, the platen 120 comprises a supporting planar member 119 having an iron backing 122 and a magnet array 124 attached to a downward-facing surface of the iron backing 122. As an example, the iron backing 122 may be in the form of a substantially flat plate made of a magnetically soft material, such as magnetically soft stainless steel. The magnet array 124 may comprise, for example, a two-dimensional array of permanent magnets 125 of alternating polarity. As another example, the magnet array 124 may be a two-dimensional Halbach array.

The platen 120, including at least the iron backing 122 and the magnet array 124, may be encapsulated in a protective shell 128. As an example, the shell may be in the form of a thin layer of substantially nonmagnetic material, such as non-magnetic stainless steel. When the system 100 is energized, the platen 120 is suspended over and separated from the support platform 110 by the gap G.

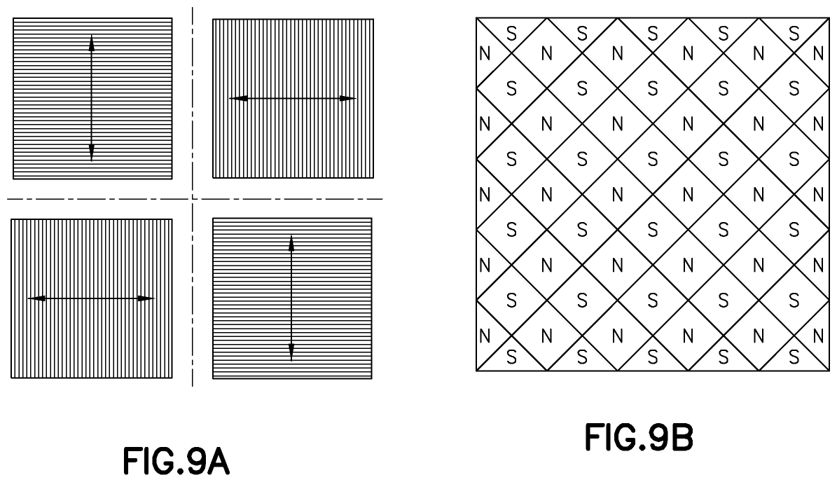

The support platform 110 comprises a plurality of actuation windings 126 configured to interact with the magnets of the magnet array 124 on the platen 120. The actuation windings 126 may comprise, for example, discrete racetrack-shaped or oval coils arranged in a suitable array, overlapping racetrack-shaped coils arranged in an array, or overlapping angled (for example, trapezoid-shaped) coils arranged in an array. Such coils may be arranged as shown with regard to FIGS. 9A-11B, as shown below.

Referring to FIGS. 1A-1C, the actuation windings 126 may be energized, either independently or in groups, to exert horizontal forces (for example, forces substantially parallel to a top surface of the support platform 110) and vertical forces (for example, forces substantially normal to the top surface of the support platform 110) on the platen 120.

In any embodiment, the actuation windings 126 may be arranged to exert independently controlled horizontal and vertical forces in at least three different non-collinear locations on the platen 120.

When the actuation windings 126 are energized, magnetic forces cause the platen 120 to be suspended in a given location above the support platform 110. Furthermore, the actuation windings 126 may be energized in a particular manner to cause linear propulsion of the platen 120 in any horizontal direction (in a plane substantially parallel with the support platform 110), move the platen 120 in the vertical direction (in the direction substantially normal to the support platform 110), or change pitch, roll, or yaw angles of the platen 120. Movements in the vertical direction, as well as the pitch and roll motions, may have limited ranges. Example actuation windings such as linear coil arrays may be seen in U.S. Pat. Nos. 6,445,093 and 6,452,292, both of which are incorporated by reference herein in their entireties.

As shown in FIG. 1C, the support platform 110 may further include a plurality of position sensors 123a, 123b, 123n arranged in sensor groups and located within, adjacent to, around, above, between, and/or below the actuation windings 126, the position sensors being configured to determine the location of the platen 120.

The position sensors 123a, 123b, 123n may be arranged to detect (measure) three-dimensional positions of at least three different non-collinear locations on the platen 120. The resulting position measurements may be used to determine the position of the platen 120 with respect to the support platform 110, for example, in terms of three Cartesian coordinates and three angular coordinates.

The support platform 110, including the actuation windings 126 and any position sensors, may be protected by a separation barrier 128. As an example, the separation barrier 128 may be a thin layer of substantially nonmagnetic material, such as non-magnetic stainless steel.

As shown in FIG. 1B, the system 100 may further comprise a control system 150 configured to energize the actuation windings 126 and move the platen 120 based on the information obtained from the position sensors and external commands. The control system 150 may include a processor 152 and at least one memory 154 storing instructions that, when executed with the at least one processor 152, carry out operations of the system 100. For example, the control system 150 may be configured to effect commutation of the actuation windings 126 for three-dimensional control of the platen 120 using forces for propulsion, lift, and guidance. In some embodiments, a portion of the control system 150 may be co-located with the actuation windings 126.

Still referring to the example of FIGS. 1A-1C, the support platform 110 and the platen 120 as well as the end effector 130 may be located in the chamber 160, such as a vacuum material transport chamber. A plurality of stations 170, such as load locks, processing modules, and/or storage cassettes, may be connected to the chamber 160 and accessible from inside the chamber 160.

Referring now to FIG. 1D, the system 100 may be embodied in the form of a positioning stage 105 comprising the support platform 110, a movable support 1120, a movable carrier 1130 having a top planar surface 1132, and the control system 150. The control system 150 may comprise at least one processor and at least one memory storing instructions that, when executed with the at least one processor, cause system 100 to carry out operations with the stage 105.

The support platform 110 in the positioning stage 105 embodiment may comprise a substantially planar top surface 1150 and a plurality of stator windings 1160 located at or below the top surface 1150, the stator windings 1160 being configured to interact with the movable support 1120 and the movable carrier 1130. The stator windings 1160 may be arranged so that, when properly energized either independently or in groups, they can exert horizontal forces (for example, forces substantially parallel to the top surface 1150 of the support platform 110) and vertical forces (for example, forces substantially normal to the top surface 1150 of the support platform 110) on the movable support 1120 and the movable carrier 1130. During operation of the system 100 incorporating the stage 105, the vertical forces cause a gap G to be formed between the top surface 1150 and the movable support 1120. More specifically, stator windings 1160 may be arranged so that they can exert independently controlled horizontal and vertical forces in at least three different non-collinear locations on the movable support 1120 and, similarly, independently controlled horizontal and vertical forces in at least three different non-collinear locations on the movable carrier 1130.

Any suitable commutation technique may be employed to energize the stator windings 1160.

As indicated in FIG. 1D, the movable support 1120 is located above the top surface 1150 of support platform 110. The movable support 1120 may comprise an iron backing 1165 and a magnet array 1170 attached to a downward-facing surface of the iron backing 1165. As an example, the iron backing 1165 may be in the form of a substantially flat square or rectangular frame made of a magnetically soft material, such as magnetically soft stainless steel. The magnet array 1170 may comprise, for example, a two-dimensional array of permanent magnets of alternating polarity. As another example, the magnet array 1170 may be a two-dimensional Halbach array.

Similarly to the movable support 1120, the movable carrier 1130 is also located above the top surface 1150 of support platform 110 and, as indicated in FIG. 1D, the movable carrier 1130 may be located inside the movable support 1120. The movable carrier 1130 may comprise an iron backing 1180 and a magnet array 1190 attached to a downward-facing surface of the iron backing 1180. For example, the iron backing 1180 may be in the form of a substantially flat plate made of a magnetically soft material, such as magnetically soft stainless steel. The magnet array 1190 may comprise, for example, a two-dimensional array of permanent magnets of alternating polarity. Alternatively, the magnet array 1190 may be a two-dimensional Halbach array.

The movable support 1120 may include an upper overhanging portion 2100, extending horizontally inward, with permanent magnets 2110 attached to a downward-facing surface of the overhanging portion 2100. The movable carrier 1130 may include an outer portion 2120 (which may be an integral part of iron backing 1180, if so desired), located below permanent magnets 2110 of the movable support 1120. Permanent magnets 2110 of the movable support 1120 and the outer portion 2120 of the movable carrier 1130 may be configured to interact with each other so that substantially vertical upward forces are exerted by the permanent magnets 2110 on outer portion 2120 of the movable carrier 1130 to completely or partially compensate for the gravitational force acting on the movable carrier 1130.

Properties of a magnetic circuit formed by the upper overhanging portion 2100 of the movable support 1120, permanent magnets 2110, and the outer portion 2120 of the movable carrier 1130 may be selected so that positioning chatter (instability) of the movable support 1120, for example due to switching control of the high electric currents associated with magnetic levitation of the movable support 1120, results in substantially inconsequential effects on the vertical upward forces exerted on the movable carrier 1130. The properties of the magnetic circuit subject to selection (and, ideally, optimization) may include the size and geometry of the components involved, the strength of the magnets, and the size of any air gap formed between components.

The configuration of FIG. 1D is a gravity compensation mechanism in which the movable support 1130 is suspended from (or supported by) the movable support 1120. Such a mechanism significantly reduces the vertical (lift) forces that are used to levitate the movable carrier 1130 relative to the support platform 110, thus significantly decreasing the corresponding electrical currents through the stator windings 1160. This may have particular advantages when it is desired to accurately hold the movable carrier 1130 in a given stationary position due to the fact that high current control, such as switching control, would produce undesirable disturbance, thus compromising positioning stability of the movable carrier 1130.

The movable carrier 1130 is further configured to accept and support a workpiece 2130 on the top planar surface 1132. As an example, the workpiece 2130 may be a semiconductor wafer.

The support platform 110 may be protected by a separation barrier 2140. As an example, the separation barrier 2140 may be implemented in the form of a thin layer of substantially non-magnetic material, such as non-magnetic stainless steel.

The support platform 110 may further include a plurality of position sensors 2150 located in or on support platform 110 and configured to determine spatial locations of the movable support 1120 and the movable carrier 1130 with respect to the support platform 110.

The position sensors 2150 may be arranged so that they can detect and measure three-dimensional positions of at least three different non-collinear locations on the movable support 1120 and on the movable carrier 1130. The resulting information measurements may be used to determine spatial locations of the movable support 1120 and the movable carrier 1130 with respect to support platform 110, for example, in terms of three Cartesian coordinates and three angular coordinates for each of the two movable objects.

Alternatively, any spatial position sensing solution suitable to determine spatial locations of the movable support 1120 and the movable carrier 1130 with respect to support platform 110 may be employed.

The control system 150 of the system 100 incorporating the stage 105 may be configured to energize the stator windings 1160, either individually or in groups, and move (in the horizontal direction) and levitate (in the vertical direction) the movable support 1120 and the movable carrier 1130 based on the information obtained from the position sensors 2150 and external commands received by the control system 150.

The control system 150 may include a master controller 2160 and power electronics 2170. As indicated in FIG. 1D, a portion of the control system 150, such as the power electronics 2170, may be conveniently collocated with the stator windings 1160 and integrated into the support platform 110. If so desired, the stator windings 1160 and the power electronics 2170 may be arranged into a plurality of integrated modules. A communication network 2180 may be utilized to transmit information in a bidirectional manner between the master controller 2160 and the power electronics 2170.

The master controller 2160 may be configured to provide power to the power electronics 2170 and other components of the system 100, receive external commands, receive position information from the position sensors 2150 and, based on the external commands and the position information from the position sensors 2150, control the power electronics 2170. Specifically, the master controller 2160 may utilize the power electronics 2170 to energize the stator windings 1160 to produce horizontal and vertical forces on the movable support 1120 and the movable carrier 1130 to move the movable support 1120 and the movable carrier 1130 in horizontal directions and to levitate the movable support 1120 and the movable carrier 1130 in the vertical direction in accordance with the external commands received.

As an example, the master controller 2160 may suspend the movable support 1120 and the movable carrier 1130 in a given location above the top surface 1150 of the support platform 110. The master controller 2160 may also utilize the power electronics 2170 and the stator windings 1160 to translate the movable support 1120 and the movable carrier 1130 in any horizontal direction (for example, in a plane substantially parallel to the top surface 1150 of the support platform 110), translate the movable support 1120 and the movable carrier 1130 in the vertical direction (for example, in a direction substantially normal to the top surface 1150 of the support platform 110), and rotate the movable support 1120 and the movable carrier 1130 to change their pitch, roll, and yaw angles (the vertical, pitch, and roll motions may have a limited range).

In general, the master controller 2160 may control the movable support 1120 and the movable carrier 1130 independently of each other. However, for the movable carrier 1130 to remain suspended from (or supported by) the movable support 1120, the master controller 2160 may control horizontal translation and yaw rotation of the movable support 120 and the movable carrier 1130 substantially in synchrony.

Utilizing the features described with respect to the above example embodiment, system 100 incorporating the stage 105 may be used to accurately position the workpiece 2130 with respect to support platform 110 and accurately maintain the workpiece 2130 in the desired position.

Although the above example embodiment shows the movable carrier 1130 to be inside the movable support 1120, the arrangement may be inverted. In other words, the movable support 1120 may be located inside the movable carrier 1130. It should also be noted that the form of the movable support 1120 and the movable carrier 1130 is not limited to square or rectangular shapes. The movable support 1120 and the movable carrier 1130 may have any suitable shapes that allow for vertical coupling between them.

In the example embodiment of FIG. 1D, the movable support 1120 utilizes the downward-facing permanent magnets to exert substantially vertical upward forces on the movable carrier 1130. Alternatively, upward-facing permanent magnets may be located on the movable carrier 1130 to achieve substantially the same effect. In general, any suitable magnetic circuit featuring permanent magnets in any suitable orientation on the movable support 1120, the movable carrier 1130, or both the movable support 1120 and the movable carrier 1130 may be utilized.

Although permanent magnets are utilized in the example embodiment of FIG. 1D to suspend the movable carrier 1130 relative to the movable support 1120, any suitable mechanism may be used to couple the movable support 1120 to the movable carrier 1130. For example, elastic elements, such as coil springs, may be used to vertically couple the movable carrier 1130 to the movable support 1120. For example, coil springs arranged in tension may be used to suspend the movable carrier 1130 from the overhanging portion 2100 of the movable support 1120, or coil springs arranged in compression may be used between an upward-facing surface of the movable support 1120 and a downward-facing surface of the movable carrier 1130 to support the movable carrier 1130 from underneath.

In the example embodiment of FIG. 1D, the stator windings 1160 are utilized to translate and rotate the movable support 1120 in any direction above the support platform 110 and levitate the movable support 1120 vertically above support platform 110.

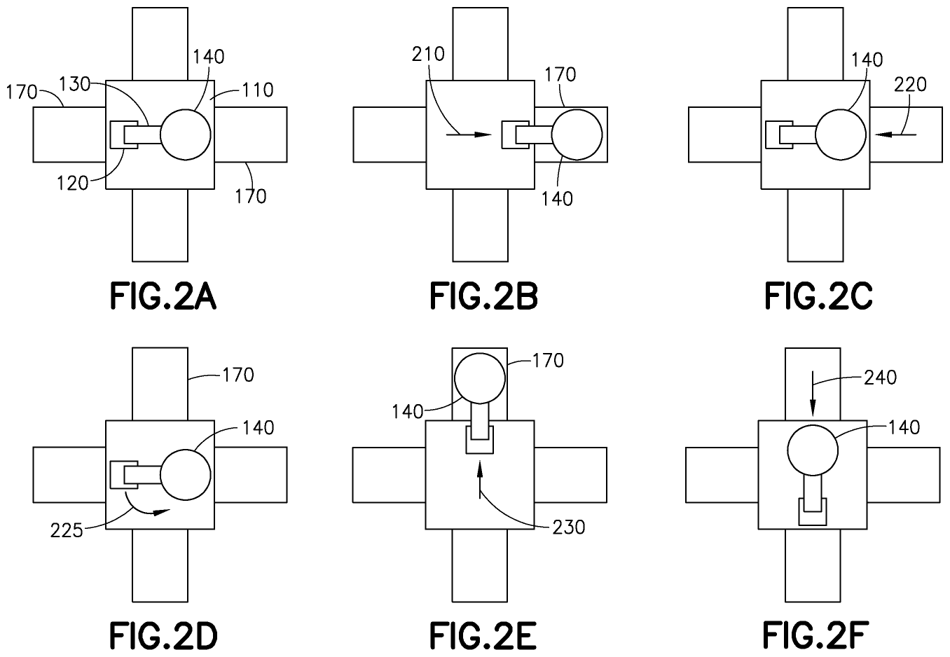

With respect to at least FIGS. 1A-1C, as illustrated diagrammatically in FIGS. 2A-2F, the platen 120 may be actuated to extend the end-effector 130 into the station 170 and either deliver (place) or retrieve (pick) the workpiece 140, which may be a silicon or glass substrate, to or from the station 170. A sequence of such operations can be used, for example, to retrieve a fresh substrate from a load lock and deliver it to a processing module, or to retrieve a processed substrate from a processing module and deliver it to a load lock. As shown in FIG. 2A, the platen 120 is at rest and located on the support platform 110 and is positioned such that the workpiece 140 is within the confines of the chamber 160. As shown in FIG. 2B, the platen 120 is controllably moved (via inputs to the control system 150) in the direction of arrow 210 to insert the workpiece 140 into the station 170. In FIG. 2C, the platen 120 is controlled to move in the direction of arrow 220 retrieve the workpiece from the station 170. In FIG. 2D, the platen 120 is again at rest and located on the support platform 110 and is positioned such that the workpiece 140 is within the confines of the chamber 160. The platen 120 is then controllably moved in the direction as indicated by arrow 225. As shown in FIG. 2E, the platen 120 is then controllably moved in the direction of arrow 230 to insert the workpiece into the station 170. As shown in FIG. 2F, the platen 120 is again controlled to move in the direction of arrow 240 retrieve the workpiece from the station 170. The present invention is not limited in this regard, however, as the stage 105 as shown in FIG. 1D may also be used to actuatably extend an end-effector into a station 170 and either deliver (place) or retrieve (pick) a workpiece.

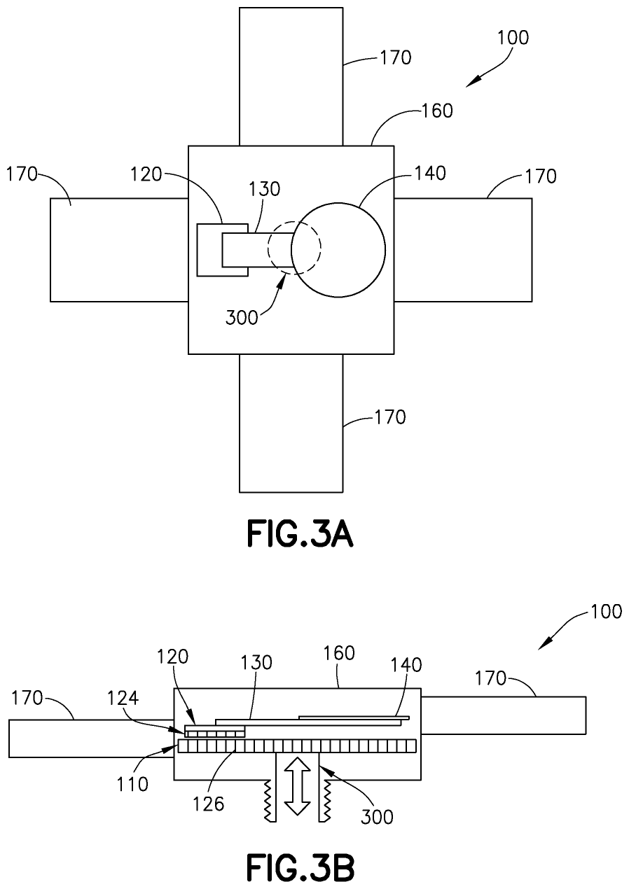

Referring now to FIGS. 3A and 3B, the system 100 may include a vertical actuator 300. In one example embodiment, the vertical actuator 300 may be a mechanism utilizing linear bearings and a ball-screw configured to move the support platform 110 in the vertical direction. This may allow the end-effector 130 to access stations 170 at substantially different elevations in the chamber 160, as shown. The vertical actuator 300 may also allow the end effector 130 to pick a substrate or workpiece 140 from a fixed shelf or fixed pins and place a substrate onto a fixed shelf or pins.

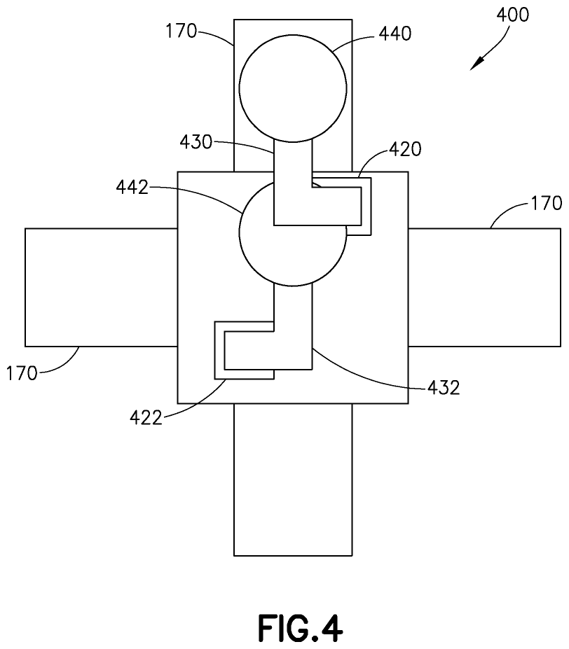

Referring now to FIG. 4, another example embodiment of a material handling system is shown generally at 400 and is hereinafter referred to as “system 400.” System 400 comprises two platens 420, 422, each having a respective end effector 430, 432 for handling respective workpieces 440, 442. The end effectors 430, 432 may be spaced from the platens 420, 422 by different vertical offsets, thereby allowing the end effectors 430, 432 to extend into two stations 170 either independently or simultaneously. Two stations 170 may be arranged one above the other. The example embodiment of system 400 may be suitable for rapid substrate exchange operations.

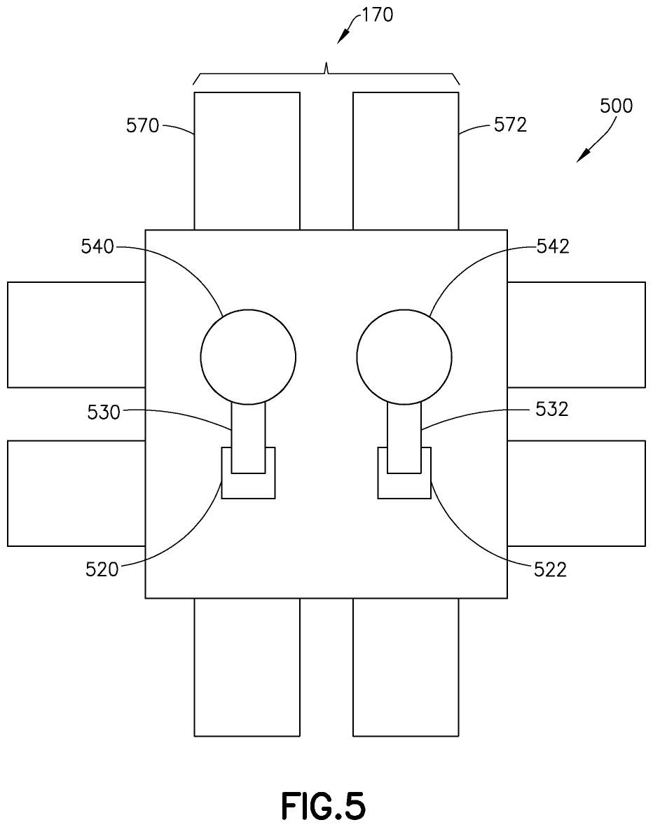

Referring now to FIG. 5, another example embodiment of a material handling system is shown generally at 500 and is hereinafter referred to as “system 500.” System 500 comprises two platens 520, 522, each having a respective end effector 530, 532 for handling respective workpieces 540, 542. In system 500, each station 170 comprises twin sub-stations 572, 574 arranged next to each other in left/right arrangements. In operating the system 500, the end effectors 530, 532 may extend to the left and right sub-stations 572, 574 either independently or simultaneously. Furthermore, the end effectors 530, 532 may transfer substrates from a left sub-station 570 to a right sub-station 572 and vice versa. When placing substrates simultaneously, independent position corrections for the left and right sub-stations 570, 572 are possible.

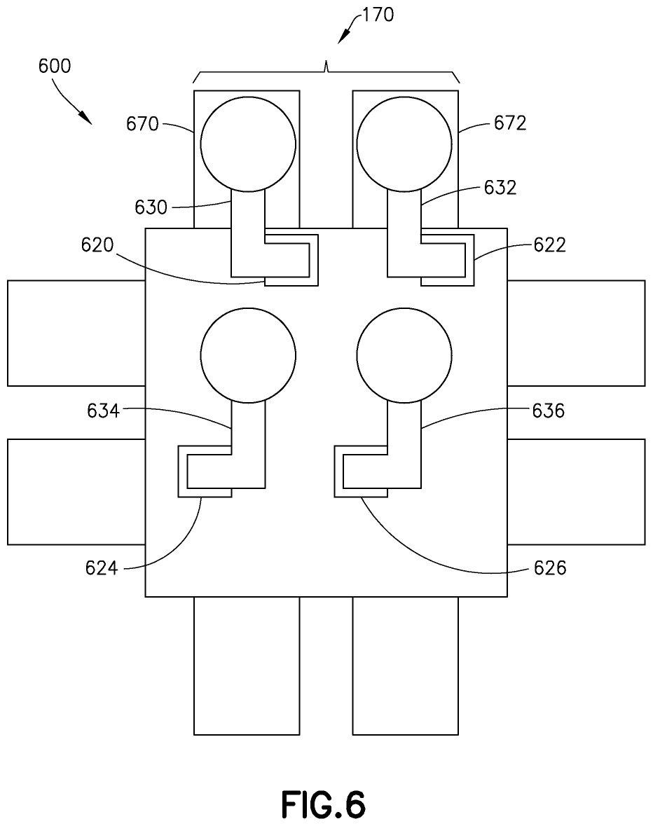

Referring now to FIG. 6, another example embodiment of a material handling system with four platens 620, 622, 624, 626, each having a respective end effector 630, 632, 634, 636, is shown generally 600 and is hereinafter referred to as “system 600.” In system 600, each station 170 again comprises twin sub-stations 670, 672 arranged next to each other in left/right arrangements. The end effectors 630, 632, 634, 636 can be utilized to transfer two pairs of substrates simultaneously. The example system 600 may be suitable for rapid exchange of a pair of substrates. Independent position corrections for the left and right sub-stations 670, 672 during a simultaneous substrate placement is possible.

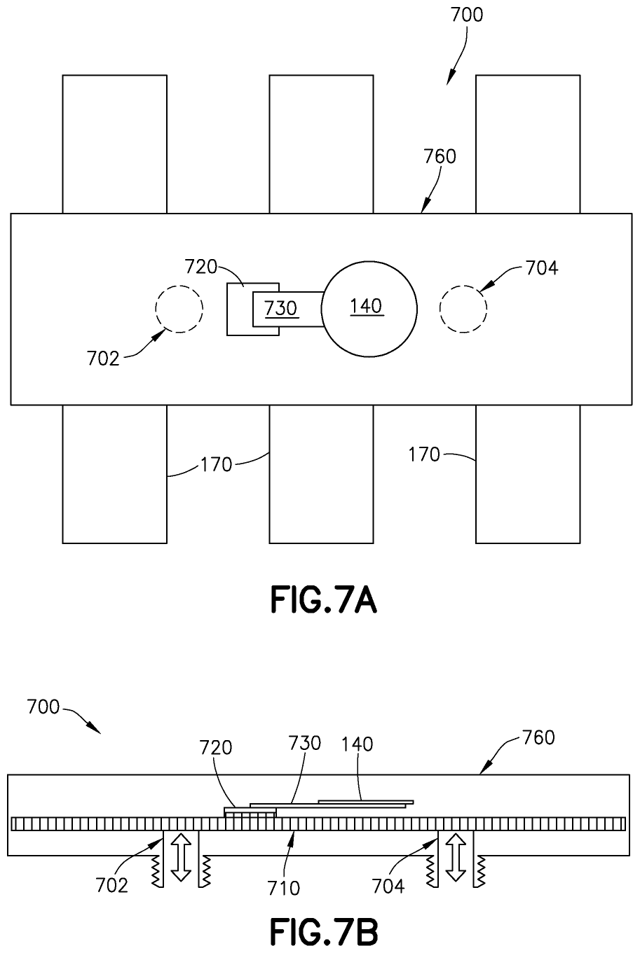

Referring now to FIGS. 7A and 7B, another example of the material handling system is shown generally at 700 and is hereinafter referred to as “system 700.” System 700 may be configured for an elongated chamber 760 and may feature a first vertical lift actuator 702 as well as a second vertical lift actuator 704. Actuation of the vertical lift actuators 702, 704, allows an elongated support platform 710 (and thereby a platen 720, end effector 730, and workpiece 140) in the elongated chamber 760 to be elevated to allow the platen 720 access to stations 170, which may or may not be at different elevations.

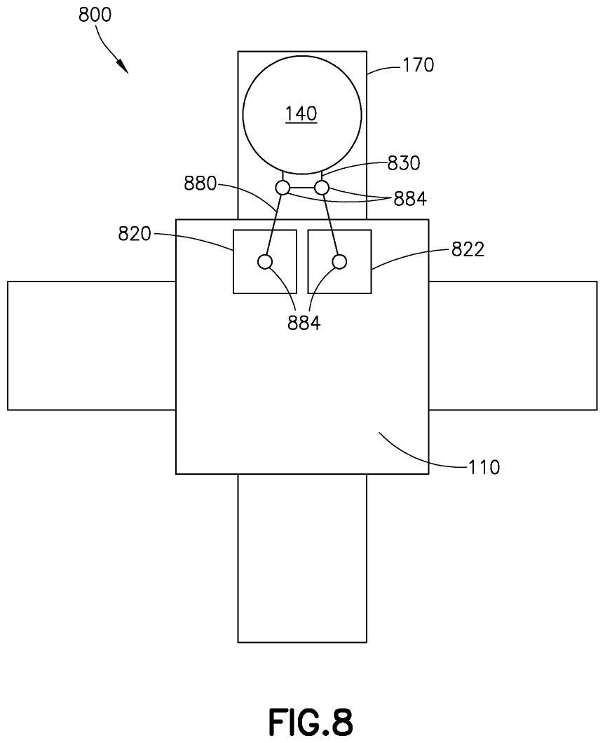

Referring now to FIG. 8, yet another example of a material handling system is shown generally at 800 and is hereinafter referred to as “system 800.” System 800 may utilize a first platen 820 and a second platen 822 on the support platform 110. The two platens 820, 822 may be operated in coordination to actuate a linkage 880, which provides a longer reach of the end effector 830 to extend the workpiece 140 into the station 170. The linkage 880 comprises multiple links articulatably connected together and to the platens 820, 822 and the end effector 830 at joints 884. Two or more linkages actuated by multiple platens may be incorporated into system 800.

The example system of FIG. 8 is not limited to the use of the linkage 880 and platens 820, 822 as described however, as the system 800 may incorporate a SCARA-type arm in which the first platen 820 and the second platen 822 rotate, thus driving arms to which one or more end effectors may be attached.

Features as described herein may be used with one or more features described in the U.S. Pat. Nos. 9,041,336; 9,330,951; 9,502,952; 10,022,789; 10,269,604; 10,538,000; and 11,929,276, which are hereby incorporated by reference in their entireties.

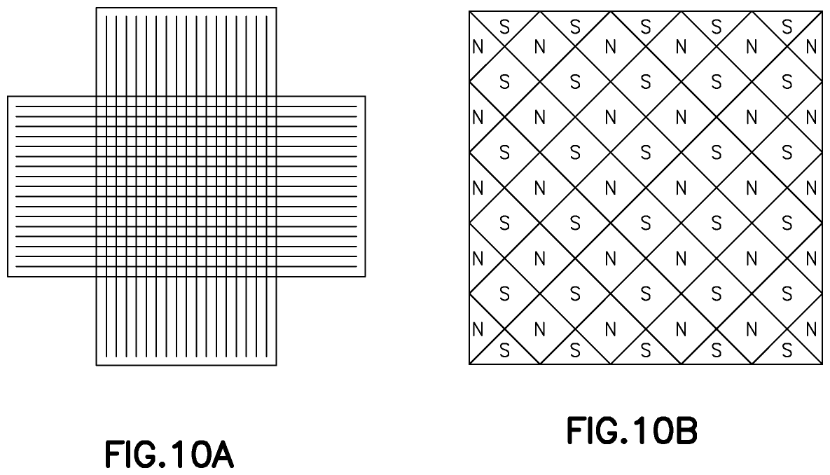

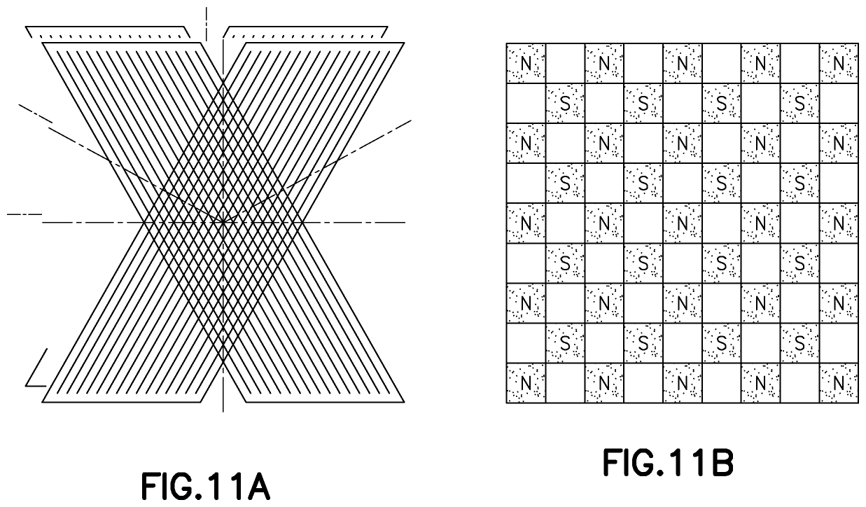

Referring now to FIGS. 9A, 9B, 10A, 10B, 11A, and 11B, various configurations of winding and magnet arrangements are shown. In FIG. 9A, winding arrangements are shown for a three-dimensional electric motor in which motion is planar (for example, in two orthogonal planes, such as X and Y planes). As shown, the windings may be arranged vertically and horizontally. In FIG. 9B, the windings of FIG. 9A may be applicable to a platen in which the magnets are arranged in diagonal rows such that the poles of the magnets alternate in polarity. In FIG. 10A, for a three-dimensional electric motor in which the motion is planar, the windings may be overlapping in the horizontal and vertical directions to provide for a higher power density. In FIG. 10B, the magnets may again be arranged in diagonal rows such that the poles of the magnets alternate in polarity. In FIG. 11A, for a three-dimensional electric motor in which the motion is planar, the windings may be angled one over the other such that asymmetric forces are possible. In FIG. 11B, the magnets may be spaced from each other horizontally and vertically but alternatingly positioned in diagonal rows such that the poles of the magnets alternate in polarity.

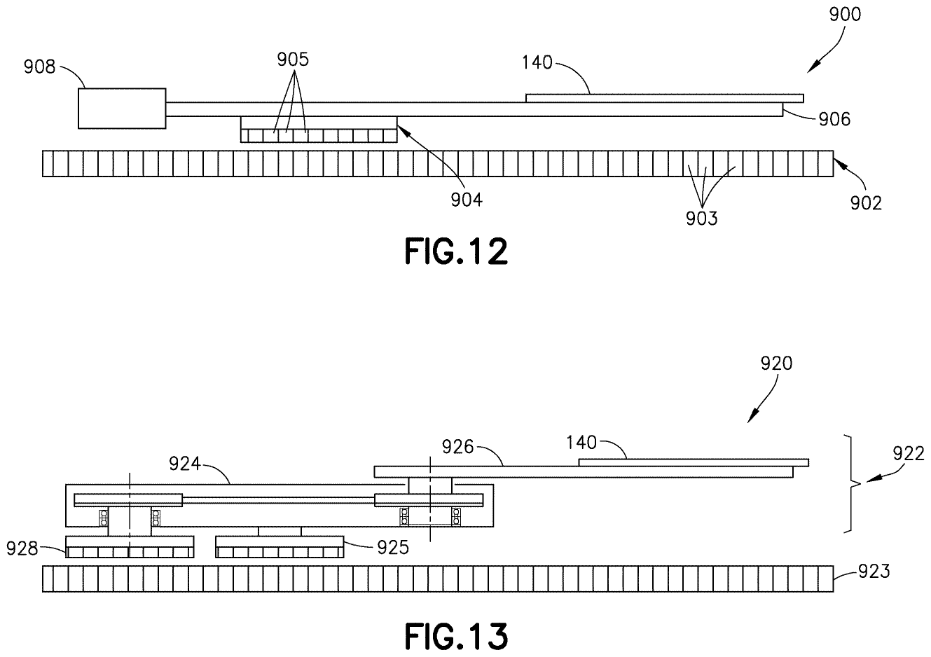

Referring now to FIG. 12, one example embodiment of a material handling system is shown generally at 900 and is hereinafter referred to as “system 900.” System 900 operates under magnetic levitation principles as described herein. System 900 comprises a support platform 902, at least one movable platen 904 (mover) positioned above the support platform 902 and separated therefrom by a gap (when the system 900 is energized), at least one end effector 906 coupled to the platen 904 and configured to hold a workpiece 140, and a counterbalance weight 908 coupled to the end effector 906 and positioned such that vertical forces acting on a portion of the end effector 906 extending from the platen 904 (for example, due to the weight of the workpiece 140) are counterbalanced. The support platform 902 includes coils 903, and the platen 904 includes magnet arrays 905. Iron backings may be included as indicated in the example embodiments described above, for example, the system 100 shown in FIGS. 1A-1C.

The counterbalancing aspect of system 900 may be carried out on a planar motor robot (for example, a magnetically levitated mover moving over a stator) using an electric field (active electromagnetic forces). Counterbalancing may involve creating a counter-force that works against gravity and inertial loads to maintain stability, levitation, and precise positioning. While electrostatic forces are generally too weak for heavy industrial robotics, “electric field” in this context usually refers to active electromagnetic field control where the system controls the magnetic field (generated by electric currents in the coils) to create opposing forces.

One way in which counterbalancing may be achieved based on advanced planar motor technology may be with active levitation and magnetic counterbalancing using six degrees of freedom. Planar motors may use a “flyway” (stator with coils) and a mover with permanent magnets. To counterbalance the weight of the mover (gravity), the controller actively generates upward magnetic forces that exactly equal the downward gravitational force. Active electromagnetic control is carried out using sensors that determine the exact position of the mover. Vertical force generation employs a controller that computes necessary currents in the stator coils to create a vertical (Z-axis) electromagnetic force, effectively acting as an active magnetic spring. The six degrees of freedom provides stability to allow the mover to stay elevated while moving in X and Y directions, providing full 6-degree-of-freedom stabilization (lifting and balancing against torque).

Another way in which counterbalancing may be achieved may be via active commutation algorithms (force decoupling). Active commutation algorithms are used to prevent the motor from tilting or losing balance when accelerating or carrying a load, and an extended commutation algorithm may be used to calculate the required current distribution. Decoupling forces result from an algorithm that separates the force used for horizontal movement (propulsion) from the force used for vertical counterbalancing (lifting). Torque cancellation may also be a factor in active commutation algorithms. In particular, if the mover begins to tilt due to an uneven load, the controller calculates the resulting torque and adjusts the currents in specific coils to counteract it, ensuring the mover remains parallel to the stators.

Still another technique used for counterbalancing involves real-time feedback and compensation. Such a system employs high-speed feedback to adjust the magnetic fields in real-time, thereby preventing vibrations and instability. Such a technique uses position sensors that are integrated and used to detect the mover's position with high precision (e.g., nanometer-level). Feedforward control is also used to predict and compensate for inertial forces during rapid movement, providing proactive counterbalancing.

Referring now to FIG. 13, another example embodiment of a material handling system is shown generally at 920 and is hereinafter referred to as “system 920.” System 920 operates under magnetic levitation principles as described herein. System 920 comprises a linkage 922 where a first link 924 is rotatably supported at a shoulder joint using a platen 925, the platen 925 being magnetically levitated on a support platform 923 using the principles described herein. The linkage 922 also comprises a second link 926 rotatably supported at an elbow joint between the first link 924 and the second link 926. The second link 926, which carries the workpiece 140 or payload, is actuated via a belt drive by a rotatable magnet platen 928. In an alternative embodiment, there may be more than one rotatable platen. For example, a plurality of rotatable platens may be magnetically levitated on the support platform 923, with one or more of the rotatable platens being configured to rotate links carrying workpieces or payloads using belt and/or cable drive mechanisms. The rotatable platens may be used in conjunction with SCARA-type arms. The platens may be rotatably configured using coaxial or non-coaxially arranged drive shafts.

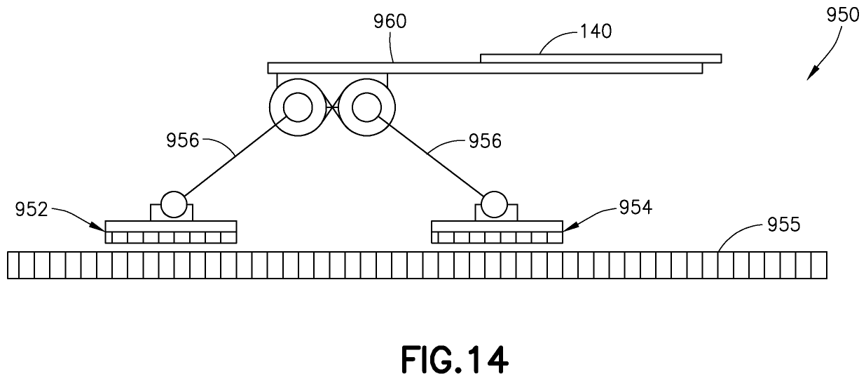

Referring now to FIG. 14, another example embodiment of a material handling system is shown generally at 950 and is hereinafter referred to as “system 950.” System 950 operates under magnetic levitation principles as described herein. System 950 comprises a first platen 952 and a second platen 954 magnetically levitated on a support platform 955, with at least one linkage 956 articulatably coupled between the first platen 952 and the second platen 954, the at least one linkage 956 being articulatably coupled to an end effector 960 on which a workpiece 140 is carried. Relative motion of the first platen 952 and the second platen 954 can be used to change elevation as an alternative (or in addition) to moving the support platform 955 or the system 950 in its entirety in vertical directions.

Although the above example embodiments show a single end effector attached to a platen or a linkage actuated by platens, two or more end effectors may be utilized. The end effectors may be rigidly connected to each other in a side-by-side configuration (for twin station systems) or in a stacked configuration (one above the other).

In one embodiment, an apparatus comprises a platform comprising a plurality of windings; a platen having a first surface facing the plurality of windings and a second surface opposing the first surface, the first surface comprising a plurality of magnets; and an end effector coupled to the second surface of the platen. The windings are configured to be energized to interact with the plurality of magnets to exert independently controllable horizontal and vertical forces in at least three different non-collinear locations on the platen.

The platen may comprise an iron backing between the first surface facing the plurality of windings and the plurality of magnets. The iron backing may be a magnetically soft stainless steel. The iron backing and the plurality of magnets may be encapsulated in non-magnetic stainless steel. The plurality of magnets may comprise a two-dimensional array of permanent magnets of alternating polarity. At least one of the windings may comprise three phased inductors arranged to provide magnetic commutation. The apparatus may further comprise at least one position sensor located on the platform. The apparatus may further comprise a control system comprising a processor and at least one memory storing instructions that, when executed with the at least one processor, carry out operations of the apparatus. The apparatus may further comprise at least one vertical actuator coupled to the platform and configured to move the platform in a vertical direction. The apparatus may further comprise a second platen, a second plurality of magnets on the second platen, and a linkage articulatably coupling the platen, the second platen, and the end effector, wherein the windings are configured to be energized to interact with the second plurality of magnets to exert independently controllable horizontal and vertical forces in at least three different non-collinear locations on the second platen.

In another embodiment, a material handling system comprises a chamber having at least one processing station extending therefrom; a material handling apparatus associated with the chamber, the material handling apparatus comprising a platform comprising a plurality of windings, a platen having a first surface facing the plurality of windings and a second surface opposing the first surface, the first surface comprising a plurality of permanent magnets of alternating polarity arranged in an array, and an end effector coupled to the second surface of the platen. The windings are configured to be energized to interact with the plurality of magnets to exert independently controllable horizontal and vertical forces in at least three different non-collinear locations on the platen. Operation of the material handling apparatus in the chamber comprises exerting the independently controllable horizontal and vertical forces on the platen to controllably move the end effector into or out of the at least one processing station.

The platen may comprise an iron backing between the first surface facing the plurality of windings and the plurality of magnets, and the iron backing and the plurality of magnets may be encapsulated in a protective shell of non-magnetic stainless steel. At least one of the windings may comprise three phased inductors configured to be energized to exert horizontal and vertical forces on the platen. The material handling system may further comprise at least one position sensor located on the platform. The material handling system may further comprise a control system comprising a processor and at least one memory storing instructions that, when executed with the at least one processor, carry out operations of the material handling apparatus in the chamber. The material handling system may further comprise at least one vertical actuator coupled to the platen, the at least one vertical actuator being configured to move the platform in a vertical direction.

In another embodiment, a material handling system comprises a chamber having at least one processing station; a material handling apparatus associated with the chamber, the material handling apparatus comprising a platform comprising a plurality of windings, at least one of the windings comprising three phased inductors arranged to provide magnetic commutation, a platen having a first surface facing the plurality of windings and a second surface opposing the first surface, the first surface comprising a plurality of permanent magnets of alternating polarity arranged in an array, and an end effector coupled to the second surface of the platen; at least one processor; and at least one memory storing instructions that, when executed with the at least one processor, cause the material handling system to energize at least one of the windings of the plurality of windings, provide a magnetic field from the energized at least one winding relative to the array of magnets on the platen, using the magnetic field, exert a force on the platen to move the platen relative to the platform, and move the end effector into or out of the at least one processing station.

The instructions, when executed with the at least one processor, may cause at least one position sensor on the platform to sense a position of the platen.

It should be understood that the foregoing description is only illustrative. Various alternatives and modifications can be devised by those skilled in the art. For example, features recited in the various dependent claims could be combined with each other in any suitable combination(s). In addition, features from different embodiments described above could be selectively combined into a new embodiment. Accordingly, the description is intended to embrace all such alternatives, modifications, and variances.

What is claimed is:

1. An apparatus, comprising:
a platform comprising a plurality of windings;
a platen having a first surface facing the plurality of windings and a second surface opposing the first surface, the first surface comprising a plurality of magnets; and
an end effector coupled to the second surface of the platen;
wherein the windings are configured to be energized to interact with the plurality of magnets to exert independently controllable horizontal and vertical forces in at least three different non-collinear locations on the platen.

2. The apparatus of claim 1, wherein the platen comprises an iron backing between the first surface facing the plurality of windings and the plurality of magnets.

3. The apparatus of claim 2, wherein the iron backing is a magnetically soft stainless steel.

4. The apparatus of claim 2, wherein the iron backing and the plurality of magnets are encapsulated in non-magnetic stainless steel.

5. The apparatus of claim 1, wherein the plurality of magnets comprises a two-dimensional array of permanent magnets of alternating polarity.

6. The apparatus of claim 1, wherein at least one of the windings comprises three phased inductors arranged to provide magnetic commutation.

7. The apparatus of claim 1, further comprising at least one position sensor located on the platform.

8. The apparatus of claim 1, further comprising a control system comprising a processor and at least one memory storing instructions that, when executed with the at least one processor, carry out operations of the apparatus.

9. The apparatus of claim 1, further comprising at least one vertical actuator coupled to the platform and configured to move the platform in a vertical direction.

10. The apparatus of claim 1, further comprising a second platen, a second plurality of magnets on the second platen, and a linkage articulatably coupling the platen, the second platen, and the end effector, wherein the windings are configured to be energized to interact with the second plurality of magnets to exert independently controllable horizontal and vertical forces in at least three different non-collinear locations on the second platen, wherein at least one of the platen and the second platen are rotatable.

11. The apparatus of claim 1, wherein the independently controllable horizontal force is configured to cause a rotation of the platen on the platform.

12. A material handling system, comprising:
a chamber having at least one processing station extending therefrom;
a material handling apparatus associated with the chamber, the material handling apparatus comprising,
a platform comprising a plurality of windings;
a platen having a first surface facing the plurality of windings and a second surface opposing the first surface, the first surface comprising a plurality of permanent magnets of alternating polarity arranged in an array; and
an end effector coupled to the second surface of the platen;
wherein the windings are configured to be energized to interact with the plurality of magnets to exert independently controllable horizontal and vertical forces in at least three different non-collinear locations on the platen;
wherein operation of the material handling apparatus in the chamber comprises exerting the independently controllable horizontal and vertical forces on the platen to controllably move the end effector into or out of the at least one processing station.

13. The material handling system of claim 12, wherein the platen comprises an iron backing between the first surface facing the plurality of windings and the plurality of magnets, and wherein the iron backing and the plurality of magnets are encapsulated in a protective shell of non-magnetic stainless steel.

14. The material handling system of claim 12, wherein at least one of the windings comprises three phased inductors configured to be energized to exert horizontal and vertical forces on the platen.

15. The material handling system of claim 12, further comprising at least one position sensor located on the platform.

16. The material handling system of claim 12, further comprising a control system comprising a processor and at least one memory storing instructions that, when executed with the at least one processor, carry out operations of the material handling apparatus in the chamber.

17. The material handling system of claim 12, further comprising at least one vertical actuator coupled to the platen, the at least one vertical actuator being configured to move the platform in a vertical direction.

18. A material handling system, comprising:
a chamber having at least one processing station;
a material handling apparatus associated with the chamber, the material handling apparatus comprising a platform comprising a plurality of windings, at least one of the windings comprising three phased inductors arranged to provide magnetic commutation, a platen having a first surface facing the plurality of windings and a second surface opposing the first surface, the first surface comprising a plurality of permanent magnets of alternating polarity arranged in an array, and an end effector coupled to the second surface of the platen;
at least one processor; and
at least one memory storing instructions that, when executed with the at least one processor, cause the material handling system to:
energize at least one of the windings of the plurality of windings;
provide a magnetic field from the energized at least one winding relative to the array of magnets on the platen;
using the magnetic field, exert a force on the platen to move the platen relative to the platform; and
move the end effector into or out of the at least one processing station.

19. The material handling system of claim 18, wherein the instructions, when executed with the at least one processor, cause at least one position sensor on the platform to sense a position of the platen.
